(19) United States
(12) Patent Application Publication
(10) Pub. No.: US 2025/0201315 A1
(43) Pub. Date: Jun. 19, 2025

(54) MEMORY DEVICE AND OPERATING METHOD OF THE MEMORY DEVICE

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 18/670,841

(22) Filed: May 22, 2024

(30) Foreign Application Priority Data
Dec. 14, 2023 (KR) 10-2023-0181556

(51) Int. Cl. G11C 16/26; G11C 16/08

(52) U.S. Cl. CPC G11C 16/26; G11C 16/08

(57) ABSTRACT

There are provided a memory device and an operating method of the memory device. The memory device includes: a memory block including a plurality of memory cells; a peripheral circuit configured to perform a plurality of read voltage applying operations and a plurality of word line setting operations on the memory block; and control logic configured to control the peripheral circuit to perform a plurality of word line setting operations to set a plurality of word line potentials of word lines included in the memory block, wherein at least one word line setting operation among the plurality of word line setting operations is used to set a word line potential higher than a word line potential set by the other word line setting operations.

### CROSS-REFERENCE TO RELATED APPLICATION

The present application claims priority under 35 U.S.C. § 119 (a) to Korean patent application number 10-2023-0181556 filed in the Korean Intellectual Property Office on Dec. 14, 2023, which application is incorporated herein by reference in its entirety.

### BACKGROUND

### 1. Technical Field

Various embodiments of the present disclosure generally relate to an electronic device, and more particularly, to a memory device and an operating method of the memory device.

### 2. Related Art

The paradigm on recent computer environment has been turned into ubiquitous computing environment in which computing systems can be used anywhere and anytime. This promotes increasing usage of portable electronic devices such as mobile phones, digital cameras, notebook computers, and the like. Such portable electronic devices may generally include a memory system using a memory device, i.e., a data storage device. The data storage device is used as a main memory device or an auxiliary memory device of the portable electronic devices.

A data storage device using a memory device has excellent stability and durability, high information access speed, and low power consumption, since there is no mechanical driving part. In an example of memory systems having such advantages, the data storage device includes a Universal Serial Bus (USB) memory device, memory cards having various interfaces, a Solid State Drive (SSD), and the like.

The memory device is generally classified into a volatile memory device and a nonvolatile memory device.

As compared to the volatile memory device, the nonvolatile memory device has relatively slow write and read speeds, but retains stored data even when the supply of power is interrupted. Thus, the nonvolatile memory device is used to store data to be retained regardless of whether power is supplied. Examples of the nonvolatile memory include a Read Only Memory (ROM), a Mask ROM (MROM), a Programmable ROM (PROM), an Electrically Programmable ROM (EPROM), an Electrically Erasable and Programmable ROM (EEPROM), a flash memory, a Phase-change RAM (PRAM), a Magnetic RAM (MRAM), a Resistive RAM (RRAM), a Ferroelectric RAM (FRAM), and the like. The flash memory is classified into a NOR type flash memory and a NAND type flash memory.

### SUMMARY

In accordance with an embodiment of the present disclosure, there is provided a memory device including: a memory block including a plurality of memory cells; a peripheral circuit configured to perform a plurality of read voltage applying operations and a plurality of word line setting operations on the memory block; and control logic configured to control the peripheral circuit to perform a plurality of word line setting operations to set a plurality of word line potentials of word lines included in the memory block, wherein at least one word line setting operation among the plurality of word line setting operations is used to set a word line potential higher than a word line potential set by the other word line setting operations.

In accordance with an embodiment of the present disclosure, there is provided a memory device including: a memory block including a plurality of memory cells; a peripheral circuit configured to alternately perform a plurality of read voltage applying operations and a plurality of word line setting operations on the memory block; and control logic configured to set a first specific word line setting operation among the plurality of word line setting operations, which is performed just before a first specific read voltage applying operation using a highest read voltage among the plurality of read voltage applying operations, to a word line potential higher than a word line potential of the other word line setting operations, and control the peripheral circuit such that word lines of the memory block have the set word line potential.

In accordance with an embodiment of the present disclosure, there is provided a method of operating a memory device, the method including: performing a first word line setting operation of controlling a plurality of word lines of a memory block to have a first voltage level; performing a first read voltage applying operation on a selected word line; performing a second word line setting operation of controlling the selected word line to have a second voltage level after the first read voltage applying operation is performed; performing a second read voltage applying operation on the selected word line; performing a third word line setting operation of controlling the selected word line to have a third voltage level after the second read voltage applying operation is performed; and performing a third read voltage applying operation on the selected word line, wherein the third voltage level of the third word line setting operation performed just before the third read voltage applying operation using a highest read voltage among the first read voltage applying operation, the second read voltage applying operation, and the third read voltage applying operation is performed is higher than each of the first voltage level and the second voltage level.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present.

Like reference numerals refer to like elements throughout.

FIG. 1 is a diagram illustrating a memory system in accordance with an embodiment of the present disclosure.

FIG. 2 is a diagram illustrating an embodiment of a memory device shown in FIG. 1.

FIG. 3 is a diagram illustrating an embodiment of a memory block shown in FIG. 2.

FIG. 4 is a diagram illustrating an embodiment of a three-dimensionally configured memory block.

FIG. 5 is a diagram illustrating a threshold voltage distribution of a triple level cell and a bit for each page, which correspond thereto, in accordance with an embodiment of the present disclosure.

FIG. 6 is a diagram illustrating a read operation of the memory device in accordance with an embodiment of the present disclosure.

FIG. 7 is a diagram illustrating voltages applied to word lines in the read operation of the memory device in accordance with an embodiment of the present disclosure.

FIG. 8 is a diagram illustrating a threshold voltage distribution of a triple level cell and a bit for each page, which correspond thereto, in accordance with an embodiment of the present disclosure.

FIG. 9 is a diagram illustrating a read operation of the memory device in accordance with an embodiment of the present disclosure.

FIG. 10 is a diagram illustrating voltages applied to word lines in the read operation of the memory device in accordance with an embodiment of the present disclosure.

FIG. 11 is a diagram illustrating an embodiment of the memory system.

FIG. 12 is a diagram illustrating an embodiment of the memory system.

FIG. 13 is a diagram illustrating an embodiment of the memory system.

FIG. 14 is a diagram illustrating an embodiment of the memory system.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, embodiments of the present disclosure will be described in detail with reference to the accompanying drawings in order for those skilled in the art to be able to readily implement the technical spirit of the present disclosure.

Various embodiments provide a memory device and an operating method of the memory device, which can increase a speed of a read operation by shortening a rising time of a read voltage corresponding to a relatively high program state.

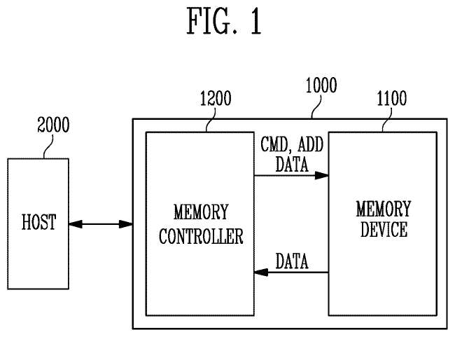

FIG. 1 is a diagram illustrating a memory system in accordance with an embodiment of the present disclosure.

Referring to FIG. 1, the memory system 1000 may include a memory device 1100 in which data is stored and a memory controller 1200 which controls the memory device 1100 under the control of a host 2000.

The host 2000 may communicate with the memory system 1000 by using an interface protocol such as Peripheral Component Interconnect-Express (PCI-E), Advanced Technology Attachment (ATA), Serial ATA (SATA), Parallel ATA (PATA), or Serial Attached SCSI (SAS). In addition, the interface protocol between the host 2000 and the memory system 1000 are not limited to the above-described example, and may be one of other interface protocols such as a Universal Serial Bus (USB), a Multi-Media Card (MMC), an Enhanced Small Disk Interface (ESDI), and an Integrated Drive Electronics (IDE).

The memory controller 1200 may control overall operations of the memory system 1000, and control data exchange between the host 2000 and the memory device 1100. For example, the memory controller 1200 may control the memory device 1100 to program or read data according to a request of the host 2000. In a program operation, the memory controller 1200 may transmit, to the memory device 1100, a command CMD corresponding to the program operation, an address ADD, and data DATA to be programmed. Also, in a read operation, the memory controller 1200 may receive and store, for a predetermined duration, data DATA read from the memory device 1100, and transmit the stored data DATA to the host 2000. The word “predetermined” as used herein with respect to a parameter, such as a predetermined duration, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The memory device 1100 may perform a program, read or erase operation under the control of the memory controller 1200.

In some embodiments, the memory device 1100 may include a Double Data Rate Synchronous Dynamic Random Access Memory (DDR SDRAM), a Low Power Double Data Rate4 (LPDDR4) SDRAM, a Graphics Double Data Rate (GDDR) SDRAM, a Low Power DDR (LPDDR), a Rambus Dynamic Random Access Memory (RDRAM), or a flash memory.

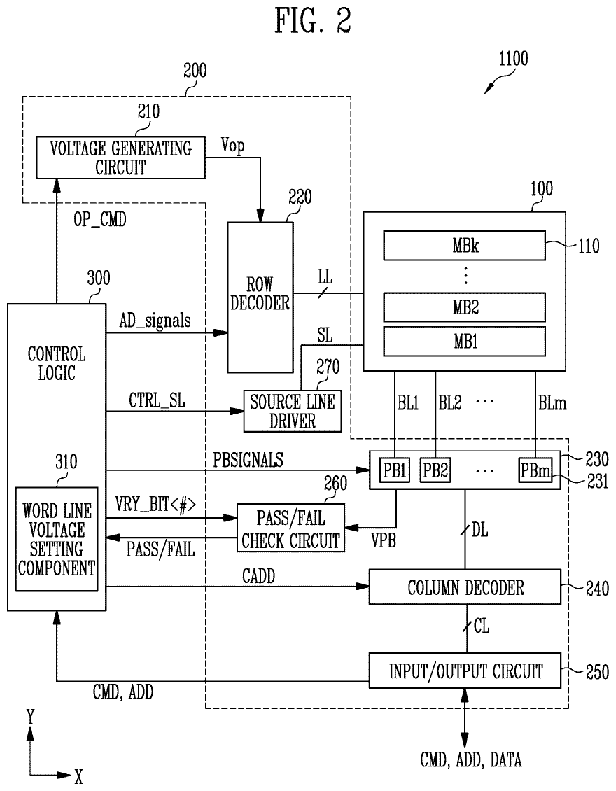

FIG. 2 is a diagram illustrating the memory device shown in FIG. 1.

Referring to FIG. 2, the memory device 1100 may include a memory cell array 100 in which data is stored. The memory device 1100 may include a peripheral circuit 200 configured to perform a program operation for storing data in the memory cell array 100, a read operation for outputting stored data, and an erase operation for erasing stored data. The memory device 1100 may include the control logic 300 which controls the peripheral circuit 200 under the control of the memory controller (1200 shown in FIG. 1). The control logic 300 may be implemented as hardware, software, or a combination of hardware and software. For example, the control logic 300 may be a control logic circuit operating in accordance with an algorithm and/or a processor executing control logic code.

The memory device 1100 in accordance with an embodiment of the present disclosure performs a plurality of read voltage applying operations respectively corresponding to a plurality of program states in a read operation, and may adjust a potential of word lines to a positive voltage level higher than 0V just before a read voltage applying operation corresponding to an uppermost program state.

The memory cell array 100 may include a plurality of memory blocks MB1 to MBk 110 (k is a positive integer). Local lines LL and the bit lines BL1 to BLm (m is a positive integer) may be connected to each of the memory blocks MB1 to MBk 110. For example, the local lines LL may include a first select line, a second select line, and a plurality of word lines arranged between the first and second select lines. Also, the local lines LL may include dummy lines arranged between the first select line and the word lines and between the second select line and the word lines. The first select line may be a source select line, and the second select line may be a drain select line. For example, the local lines LL may include word lines, drain and source select lines, and source lines SL. For example, the local lines LL may further include dummy lines. For example, the local lines LL may further include pipe lines. The local lines LL may be connected to each of the memory blocks MB1 to MBk 110, and the bit lines BL1 to BLm may be commonly connected to the memory blocks MB1 to MBk 110. The memory blocks MB1 to MBk 110 may be implemented in a two-dimensional or three-dimensional structure. For example, memory cells may be arranged in a direction parallel to a substrate in the memory blocks 110 having the two-dimensional structure. For example, memory cells may be stacked in a direction vertical to a substrate in the memory blocks 110 having the three-dimensional structure.

The peripheral circuit 200 may be configured to perform program, read, and erase operations of a selected memory block 110 under the control of the control logic 300. For example, the peripheral circuit 200 may include a voltage generating circuit 210, a row decoder 220, a page buffer group 230, a column decoder 240, an input/output circuit 250, a pass/fail check circuit 260, and a source line driver 270.

The voltage generating circuit 210 may generate various operating voltages Vop used for program, read, and erase operations in response to an operation signal OP_CMD. Also, the voltage generating circuit 210 may selectively discharge the local lines LL in response to the operation signal OP_CMD. For example, the voltage generating circuit 210 may generate a program voltage, a verify voltage, a read voltage, a pass voltage, a plurality of setting voltages, and the like under the control of the control logic 300. The voltage generating circuit 210 may adjust the potential of the word lines to a set value after a read voltage apply operation under the control of a word line voltage setting component 310 of the control logic 300.

The row decoder 220 may transfer the operating voltages Vop to the local lines LL connected to the selected memory block 110 in response to row decoder control signals AD_signals. For example, in a program operation, the row decoder 220 may apply the program voltage generated by the voltage generating circuit 210 to a selected word line among the local lines LL and apply the pass voltage generated by the voltage generating circuit 210 to unselected word lines, in response to the row decoder control signals AD_signals. In a read operation, the row decoder 220 may sequentially apply a plurality of read voltages generated by the voltage generating circuit 210 to the selected word line among the local lines LL and apply the pass voltage generated by the voltage generating circuit 210 to the unselected word lines, in response to the row decoder control signals AD_signals.

The page buffer group 230 may include a plurality of page buffers PB1 to PBm 231 connected to the bit lines BL1 to BLm. The page buffers PB1 to PBm 231 may be operated in response to page buffer control signals PBSIGNALS. For example, in a program operation, the page buffers PB1 to PBm 231 may store, for a predetermined duration, data to be programmed and control a potential level of the bit lines BL1 to BLm, based on the stored data to be programmed. Also, in a read or program verify operation, the page buffers PB1 to PBm 231 may sense a voltage or current of the bit lines BL1 to BLm.

The column decoder 240 may transfer data between the input/output circuit 250 and the page buffer group 230 in response to a column address CADD. For example, the column decoder 240 may exchange data with the page buffers 231 through data lines DL, or exchange data with the input/output circuit 250 through column lines CL.

The input/output circuit 250 may transfer a command CMD and an address ADD, which are transferred from the memory controller (1200 shown in FIG. 1), to the control logic 300, or exchange data DATA with the column decoder 240.

In a read operation or a program verify operation, the pass/fail check circuit 260 may generate a reference current in response to an allow bit VRY_BIT<#>, and output a pass signal PASS or a fail signal FAIL by comparing a sensing voltage VPB received from the page buffer group 230 with a reference voltage generated by the reference current. The sensing voltage VPB may be a voltage controlled based on a number of memory cells determined as pass in the program verify operation.

The source line driver 270 may be connected to a memory cell included in the memory cell array 100 through the source line SL, and control a voltage applied to the source line SL. The source line driver 270 may receive a source line control signal CTRL_SL from the control logic 300, and control a source line voltage applied to the source line SL, based on the source line control signal CTRL_SL.

The control logic 300 may control the peripheral circuit 200 by outputting the operation signal OP_CMD, the row decoder control signals AD_signals, the page buffer control signals PBSIGNALS, and the allow bit VRY_BIT<#> in response to the command CMD and the address ADD. The control logic 300 may control the peripheral circuit 200 to perform a read operation on a selected memory block. For example, the control logic 300 may control the peripheral circuit 200 to perform read voltage applying operations of applying a plurality of read voltages respectively corresponding to a plurality of program states in the read operation on the selected memory block. Also, when one read voltage applying operation is completed, the control logic 300 may control the peripheral circuit 200 to perform a word line setting operation of controlling word lines of the selected memory block at a set level before a next read voltage applying operation is performed. The control logic 300 may control the peripheral circuit 200 such that a potential of the word lines has a positive voltage level higher than 0V in a word line setting operation just before a read voltage applying operation including a read voltage corresponding to an uppermost program state among the plurality of read voltages is performed.

The control logic 300 may include the word line voltage setting component 310. The word line voltage setting component 310 may set a potential of word lines in a word line setting operation between a plurality of read voltage applying operations. The word line voltage setting component 310 may control the peripheral circuit 200 such as the potential of the word lines has a positive voltage level higher than 0V in a word line setting operation just before a specific read voltage applying operation including a read voltage corresponding to an uppermost program state among a plurality of read voltages is performed. Also, the word line voltage setting component 310 may control the peripheral circuit 200 such that the potential of the word lines becomes 0V in a word line setting operation just before the other read voltage applying operations except the specific read voltage applying operation are performed.

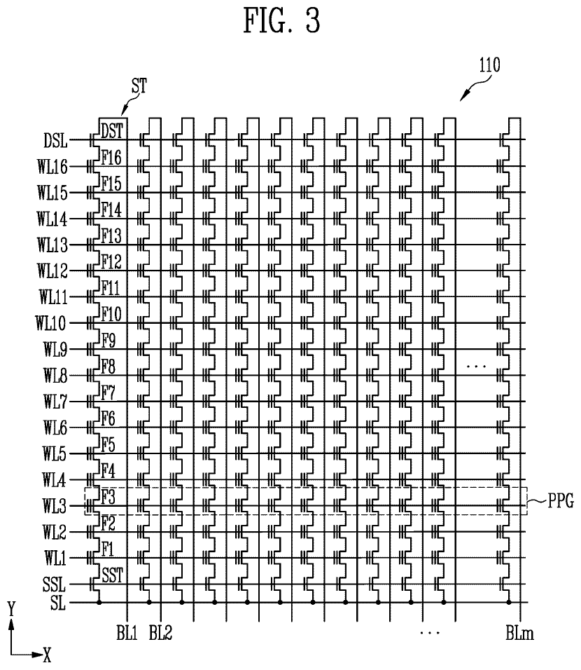

FIG. 3 is a diagram illustrating the memory block shown in FIG. 2.

Referring to FIG. 3, in the memory block 110, a plurality of word lines arranged in parallel to one another may be connected between a first select line and a second select line. The first select line may be a source select line SSL, and the second select line may be a drain select line DSL. For example, the memory block 110 may include a plurality of strings ST connected between bit lines BL1 to BLm and a source line SL. The bit lines BL1 to BLm may be connected to the strings ST, respectively, and the source line SL may be commonly connected to the strings ST. The strings ST may be configured identically to one another, and therefore, a string ST connected to a first bit line BL1 will be described in detail as an example.

The string ST may include a source select transistor SST, a plurality of memory cells F1 to F16, and a drain select transistor DST, which are connected in series between the source line SL and the first bit line BL1. At least one source select transistor SST and at least one drain select transistor DST may be included in one string ST, and memory cells of which number is greater than that of the memory cells F1 to F16 shown in the drawing may be included in the one string ST.

A source of the source select transistor SST may be connected to the source line SL, and a drain of the drain select transistor DST may be connected to the first bit line BL1. The memory cells F1 to F16 may be connected in series between the source select transistor SST and the drain select transistor DST. Gates of source select transistors SST included in different strings ST may be connected to the source select line SSL, gates of drain select transistors DST included in different strings ST may be connected to the drain select line DSL, and gates of memory cells F1 to F16 included in different strings ST may be connected to a plurality of word lines WL1 to WL16. A group of memory cells connected to the same word line among memory cells included in different strings ST may be referred as a physical page PPG. Therefore, physical pages PPG of which number corresponds to that of the word lines WL1 to WL16 may be included in the memory block 110.

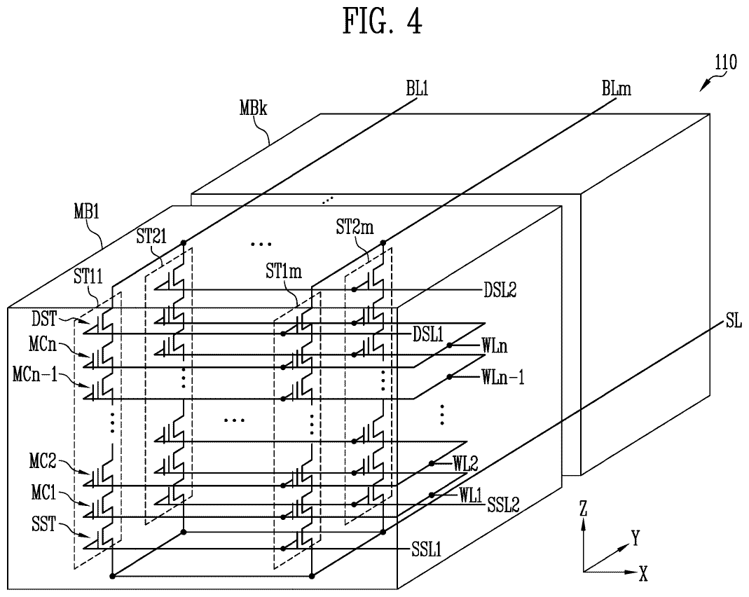

FIG. 4 is a diagram illustrating an embodiment of a three-dimensionally configured memory block.

Referring to FIG. 4, the memory cell array 100 may include a plurality of memory blocks MB1 to MBk 110. The memory block 110 may include a plurality of strings ST11 to ST1m and ST21 to ST2m. In an embodiment, each of the plurality of strings ST11 to ST1m and ST21 to ST2m may be formed in an ‘I’ shape or a ‘U’ shape. In a first memory block MB1, m strings may be arranged in a row direction (X direction). Although a case where two strings are arranged in a column direction (Y direction) is illustrated in FIG. 4, this is for convenience of description, and three or more strings may be arranged in the column direction (Y direction). Each of the plurality of strings ST11 to ST1m and ST21 to ST2m may include at least one source select transistor SST, first to nth memory cells MC1 to MCn, and at least one drain select transistor DST.

The source select transistor SST of each string may be connected between a source line SL and memory cells MC1 to MCn. Source select transistors of strings arranged on the same row may be connected to the same source select line. Source select transistors of strings ST11 to ST1m arranged on a first row may be connected to a first source select line SSL1. Source select transistors of strings ST21 to ST2m arranged on a second row may be connected to a second source select line SSL2. In another embodiment, the source select transistors of the strings ST11 to ST1m and ST21 to ST2m may be commonly connected to one source select line.

The first to nth memory cells MC1 to MCn of each string may be connected in series to each other between the source select transistor SST and the drain select transistor DST. Gates of the first to nth memory cells MC1 to MCn may be respectively connected to first to nth word lines WL1 to WLn.

In an embodiment, at least one of the first to nth memory cells MC1 to MCn may be used as a dummy memory cell. When the dummy memory cell is provided, in an embodiment, a voltage or current of a corresponding string can be stably controlled. Accordingly, in an embodiment, the reliability of data stored in the memory block 110 can be improved.

The drain select transistor DST of each string may be connected between a bit line and the memory cells MC1 to MCn. Drain select transistors DST of strings arranged in the row direction may be connected to a drain select line extending in the row direction. Drain select transistors DST of the strings ST11 to ST1m on the first row may be connected to a first drain select line DSL1. Drain select transistors DST of the strings ST21 to ST2m on the second row may be connected to a second drain select line DSL2.

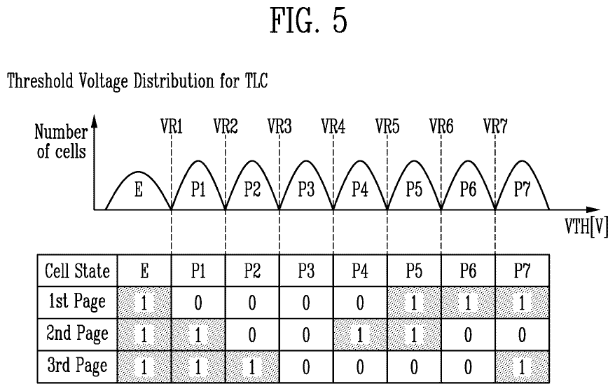

FIG. 5 is a diagram illustrating a threshold voltage distribution of a triple level cell and a bit for each page, which correspond thereto, in accordance with an embodiment of the present disclosure.

Referring to FIG. 5, this embodiment will be described with reference to a graph of a triple level cell (TLC). The horizontal axis represents threshold voltage (e.g., level of threshold voltage), and the vertical axis represents number of memory cells. The TCL may have one state among an erase state E and first to seventh program states P1, P2, P3, P4, P5, P6, and P7, in which the threshold voltage distribution is sequentially increased.

In the TLC, a first read voltage VR1 may be a voltage for distinguishing the erase state E and the first program state P1 from each other. A second read voltage VR2 may be a voltage for distinguishing the first program state P1 and the second program state P2 from each other. A third read voltage VR3 may be a voltage for distinguishing the second program state P2 and the third program state P3 from each other. A fourth read voltage VR4 may be a voltage for distinguishing the third program state P3 and the fourth program state P4 from each other. A fifth read voltage VR5 may be a voltage for distinguishing the fourth program state P4 and the fifth program state P5 from each other. A sixth read voltage VR6 may be a voltage for distinguishing the fifth program state P5 and the sixth program state P6 from each other. A seventh read voltage VR7 may be a voltage for distinguishing the sixth program state P6 and the seventh program state P7 from each other.

Referring to a table of the TLC, a first logical page bit 1st Page, a second logical page bit 2nd Page, and a third logical page bit 3rd Page according to a cell state are illustrated. The first logical page bit 1st Page, the second logical page bit 2nd Page, and the third logical page bit 3rd Page may be a Least Significant Bit (LSB), a Center Significant Bit (CSB), and a Most Significant Bit (MSB). In an embodiment, the first logical page bit 1st Page, the second logical page bit 2nd Page, and the third logical page bit 3rd Page may be a Least Significant Bit (LSB), a Center Significant Bit (CSB), and a Most Significant Bit (MSB), respectively. In an embodiment, the first logical page bit 1st Page, the second logical page bit 2nd Page, and the third logical page bit 3rd Page may be a Most Significant Bit (MSB), a Center Significant Bit (CSB), and a Least Significant Bit (LSB), respectively.

A read voltage applying operation may be performed for each logical page bit in a read operation of a memory block including the above-described TLCs. For example, a first read voltage applying operation of applying the first read voltage VR1 and the fifth read voltage VR5 may be performed to read the first logical page bit 1st Page, a second read voltage applying operation of applying the second read voltage VR2, the fourth read voltage VR4, and the sixth read voltage VR6 may be performed to read the second logical page bit 2nd Page, and a third read voltage applying operation of applying the third read voltage VR3 and the seventh read voltage VR7 may be performed to read the third logical page bit 3rd Page.

The first read voltage applying operation, the second read voltage applying operation, and the third read voltage applying operation may be sequentially performed.

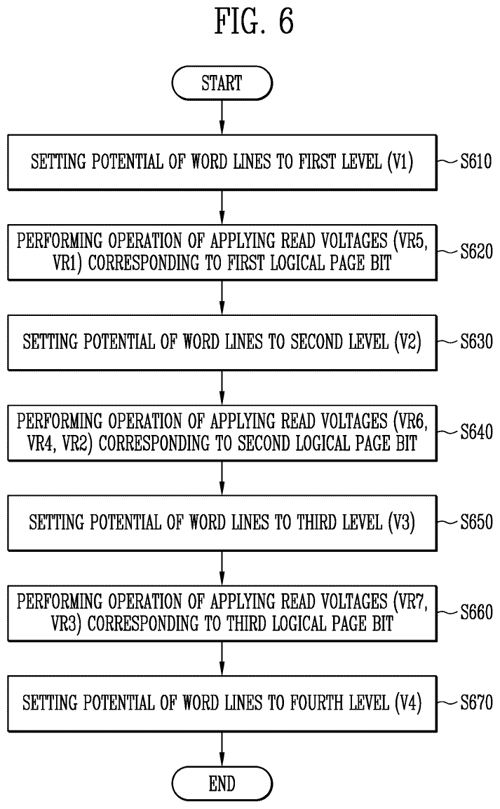

FIG. 6 is a diagram illustrating a read operation of the memory device in accordance with an embodiment of the present disclosure.

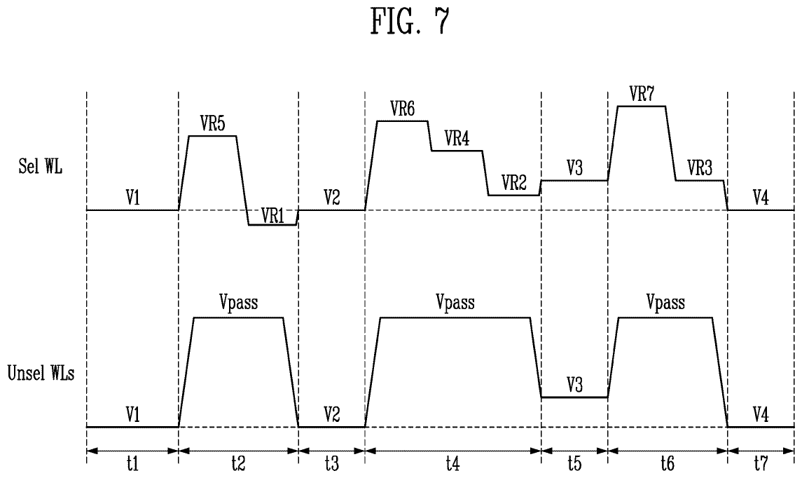

FIG. 7 is a diagram illustrating voltages applied to word lines in the read operation of the memory device in accordance with an embodiment of the present disclosure.

A read operation of the memory device in accordance with an embodiment of the present disclosure will be described as follows with reference to FIGS. 2 to 7.

In the embodiment of the present disclosure, a read operation on one selected word line of a selected memory block (e.g., MB1) including TLCs will be described as an example.

In step S610, the word line voltage setting component 310 of the control logic 300 sets, as a potential of a first voltage V1, a potential of a selected word line Sel WL and unselected word lines Unsel WLs of a selected memory block MB1. The first voltage V1 may be 0V or a positive voltage higher than 0V.

The voltage generating circuit 210 generates the first voltage V1 under the control of the word line voltage setting component 310, and the row decoder 220 applies the first voltage V1 to the selected word line Sel WL and the unselected word lines Unsel WL of the selected memory block MB1, thereby performing a word line setting operation. That is, in a duration of time t1, the first voltage V1 is applied to the selected word line Sel WL and the unselected word lines Unsel WL.

In step S620, the control logic 300 controls the peripheral circuit 200 to perform a first read voltage applying operation for reading a first logical page bit 1st Page among a plurality of logical page bits stored in memory cells connected to the selected word line Sel WL.

The first read voltage applying operation may be an operation of applying, to the selected word line Sel WL, a first read voltage VR1 and a fifth read voltage VR5, which can sort a data value of the first logical page bit 1st Page as 0 or 1. In the first read voltage applying operation, the fifth read voltage VR5 having a high potential level, which is selected from the first read voltage VR1 and the fifth read voltage VR5, may be first applied to the selected word line Sel WL, and then the first read voltage VR1 may be applied to the selected word line Sel WL.

For example, the voltage generating circuit 210 may sequentially generate the fifth read voltage VR5 and the first read voltage VR1 under the control of the control logic 300. The row decoder 220 applies the fifth read voltage VR5 to the selected word line Sel WL of the selected memory block MB1 for a certain time, and then applies the first read voltage VR1 to the selected word line Sel WL of the selected memory block MB1 for a certain time. Also, the voltage generating circuit 210 generates a pass voltage Vpass. The row decoder 220 applies the pass voltage Vpass to the unselected word lines Unsel WLs while the first read voltage VR5 and the first read voltage VR1 are applied to the selected word line Sel WL. That is, in a duration of time t2, the fifth read voltage VR5 and the first read voltage VR1 are sequentially applied to the selected word line Sel WL, and the pass voltage Vpass is applied to the unselected word lines Unsel WLs.

After that, the page buffer group 230 senses a voltage or current of the bit lines BL1 to BLm, thereby storing the data value of the first logical page bit 1st Page of the memory cells connected to the selected word line Sel WL.

In step S630, the word line voltage setting component 310 of the control logic 300 sets, as a potential of a second voltage V2, the potential of the selected word line Sel WL and the unselected word lines Unsel WLs of a selected memory block MB1. The second voltage V2 may have the same potential as the first voltage V1. For example, the second voltage V2 may be 0V or a positive voltage higher than 0V.

The voltage generating circuit 210 generates the second voltage V2 under the control of the word line voltage setting component 310, and the row decoder 220 applies the second voltage V2 to the selected word line Sel WL and the unselected word lines Unsel WLs of a selected memory block MB1, thereby performing a word line setting operation. That is, in a duration of time t3, the second voltage V2 is applied to the selected word line Sel WL and the unselected word lines Unsel WLs.

In an embodiment, when the potential of the selected word line Sel WL is higher than the potential of the second voltage V2, the row decoder 220 may discharge the potential of the selected word line Sel WL and the unselected word lines Unsel WLs to a level of the second voltage V2 without the voltage generation operation of the voltage generating circuit 210.

In step S640, the control logic 300 controls the peripheral circuit 200 to perform a second read voltage applying operation for reading a second logical page bit 2nd Page among the plurality of logical page bits stored in the memory cells connected to the selected word line Sel WL.

The second read voltage applying operation may be an operation of applying, to the selected word line Sel WL, a second read VR2, a fourth read voltage VR4, and a sixth read voltage VR6, which can sort a data value of the second logical page bit 2nd Page as 0 or 1. In the second read voltage applying operation, the sixth read voltage VR6, the fourth read voltage VR4, and the second read voltage VR2 may be sequentially applied to the selected word line Sel WL in an order a potential level is high among the second read voltage VR2, the fourth read voltage VR4, and the sixth read voltage VR6.

For example, the voltage generating circuit 210 may sequentially generate the sixth read voltage VR6, the fourth read voltage VR4, and the second read voltage VR2 under the control of the control logic 300. The row decoder 220 applies the sixth read voltage VR6 to the selected word line Sel WL of the selected memory block MB1 for a certain time, and then applies the fourth read voltage VR4 to the selected word line Sel WL of the selected memory block MB1 for a certain time. After that, the row decoder 220 applies the second read voltage VR2 to the selected word line Sel WL of the selected memory block MB1 for a certain time.

Also, the voltage generating circuit 210 generates the pass voltage Vpass. The row decoder 220 applies the pass voltage Vpass to the unselected word lines Unsel WLs while the sixth read voltage VR6, the fourth read voltage VR4, and the second read voltage VR2 are applied to the selected word line Sel WL. That is, in a duration of time t4, the sixth read voltage VR6, the fourth read voltage VR4, and the second read voltage VR2 are sequentially applied to the selected word line Sel WL, and the pass voltage Vpass is applied to the unselected word lines Unsel WLs.

After that, the page buffer group 230 senses a voltage or current of the bit lines BL1 to BLm, thereby storing the data value of the second logical page bit 2nd Page of the memory cells connected to the selected word line Sel WL.

In step S650, the word line voltage setting component 310 of the control logic 300 sets, a potential of a third voltage V3, the potential of the selected word line Sel WL and the unselected word lines Unsel WLs of the selected memory block MB1. The third voltage V3 may have a potential higher than the potential of each of the first voltage V1 and the second voltage V2. For example, the third voltage V3 may be a positive voltage higher than 0V. In an embodiment, the word line voltage setting component 310 may set the potential of the word lines to a positive voltage level higher than 0V just before a read voltage apply operation using a seventh read voltage VR7 corresponding to a seventh program state P7 as a relatively high threshold voltage distribution among a plurality of program states P1 to P7. That is, the control logic 300 may control the peripheral circuit 200 to adjust the potential of the word lines to a positive voltage level higher than 0V just before the seventh read voltage VR7 having the highest potential level among a plurality of read voltages VR1 to VR7 respectively corresponding to the plurality of program states P1 to P7 is applied to the selected word line Sel WL. As used herein, executing a first operation just before a second operation means there are no additional operations between the first and second operations. For example, the word line setting operation for setting the third voltage V3 is performed just before the read voltage apply operation using the seventh read voltage VR7 as shown in FIG. 7.

The voltage generating circuit 210 generates the third voltage V3 under the control of the word line voltage setting component 310, and the row decoder 220 applies the third voltage V3 to the selected word line Sel WL and the unselected word lines Unsel WLs of the selected memory block MB1, thereby performing a word line setting operation. That is, in a duration of time t5, the third voltage V3 is applied to the selected word line Sel WL and the unselected word lines Unsel WLs.

In another embodiment, when the potential of the selected word line Sel WL is higher than the potential of the third voltage V3, the row decoder 220 may discharge the potential of the selected word line Sel WL and the unselected word lines Unsel WLs to a level of the third voltage V3 without the voltage generation operation of the voltage generating circuit 210.

In step S660, the control logic 300 controls the peripheral circuit 200 to perform a third read voltage applying operation for reading a third logical page bit 3rd Page among the plurality of logical page bits stored in the memory cells connected to the selected word line Sel WL.

The third read voltage applying operation may be an operation of applying, to the selected word line Sel WL, a third read voltage VR3 and the seventh read voltage VR7, which can sort a data value of the third logical page bit 3rd Page as 0 or 1. In the third read voltage applying operation, the seventh read voltage VR7 having a high potential level, which is selected from the third read voltage VR3 and the seventh read voltage VR7, may be first applied to the selected word line Sel WL, and then the third read voltage VR3 may be applied to the selected word line Sel WL.

For example, the voltage generating circuit 210 may sequentially generate the seventh read voltage VR7 and the third read voltage VR3 under the control of the control logic 300. The row decoder 220 applies the seventh read voltage VR7 to the selected word line Sel WL of the selected memory block MB1 for a certain time, and then applies the third read voltage VR3 to the selected word line Sel WL of the selected memory block MB1 for a certain time. Also, the voltage generating circuit 210 generates the pass voltage Vpass. The row decoder 220 applies the pass voltage Vpass to the unselected word lines Unsel WLs while the seventh read voltage VR7 and the third read voltage VR3 are applied to the selected word line Sel WL. That is, in a duration of time t6, the seventh read voltage VR7 and the third read voltage VR3 are sequentially applied to the selected word line Sel WL, and the pass voltage Vpass is applied to the unselected word lines Unsel WLs.

After that, the page buffer group 230 senses a voltage or current of the bit lines BL1 to BLm, thereby storing the data value of the third logical page bit 3rd Page of the memory cells connected to the selected word line Sel WL.

The voltage generating circuit 210 increases the potential of the word lines, which is controlled to a positive voltage level in the duration of time t5, to a level of the seventh read voltage VR7 in the duration of time t6. In an embodiment of an operation of increasing the potential of the word lines from a level of the third voltage V3 having a positive potential to the level of the seventh read voltage VR7, an operation time is decreased and power consumption of the voltage generating circuit 210 is also decreased, as compared with an operation of increasing the potential of the word lines from 0V to the level of the seventh read voltage VR7.

In step S670, the word line voltage setting component 310 of the control logic 300 sets, a potential of a fourth voltage V4, the potential of the selected word line Sel WL and the unselected word lines Unsel WLs of the selected memory block MB1. The fourth voltage V4 may have the same potential as the first voltage V1 and the second voltage V2. For example, the fourth voltage V4 may be 0V or a positive voltage higher than 0V. In some embodiments, executing a second operation just after a first operation means there are no additional operations between the first and second operations. For example, the fourth word line setting operation of controlling the selected word line Sel WL to have a fourth voltage level V4 is performed just after the performance of the third read voltage applying operation on the selected word line Sel WL as shown in FIG. 7.

The row decoder 220 may discharge the potential of the selected word line Sel WL and the unselected word lines Unsel WLs to a level of the fourth voltage V4, thereby performing a word line setting operation.

In the above-described embodiment of the present disclosure, it has been described that the potential of the word lines is set to a positive voltage level just before the seventh read voltage having a relatively highest potential among the plurality of read voltages is applied to the selected word line Sel WL. In another embodiment, the potential of the word lines may be set to a positive voltage level just before at least one read voltage having a relatively high potential among the plurality of read voltages is applied to the selected word line Sel WL. For example, the potential of the word lines may be set to the third voltage V3 just before the third read voltage applying operation using the seventh read voltage VR7, and the potential of the word lines may be set to a level which is the third voltage V3 or is lower than the third voltage V3 and higher than the first voltage V1 just before the second read voltage applying operation using the sixth read voltage VR6.

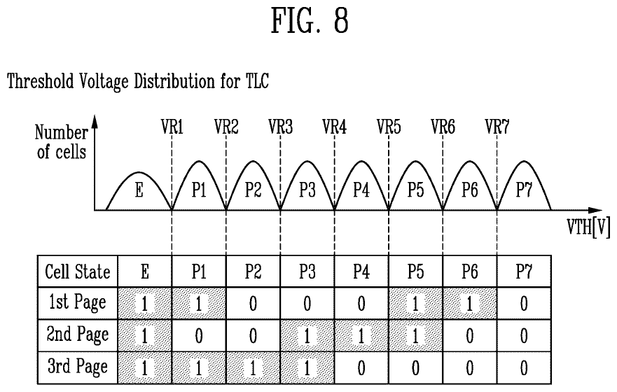

FIG. 8 is a diagram illustrating a threshold voltage distribution of a triple level cell and a bit for each page, which correspond thereto, in accordance with an embodiment of the present disclosure.

Referring to FIG. 8, this embodiment will be described with reference to a graph of a triple level cell (TLC). The horizontal axis represents threshold voltage (e.g., level of threshold voltage), and the vertical axis represents number of memory cells. The TCL may have one state among an erase state E and first to seventh program states P1, P2, P3, P4, P5, P6, and P7, in which the threshold voltage distribution is sequentially increased.

In the TLC, a first read voltage VR1 may be a voltage for distinguishing the erase state E and the first program state P1 from each other. A second read voltage VR2 may be a voltage for distinguishing the first program state P1 and the second program state P2 from each other. A third read voltage VR3 may be a voltage for distinguishing the second program state P2 and the third program state P3 from each other. A fourth read voltage VR4 may be a voltage for distinguishing the third program state P3 and the fourth program state P4 from each other. A fifth read voltage VR5 may be a voltage for distinguishing the fourth program state P4 and the fifth program state P5 from each other. A sixth read voltage VR6 may be a voltage for distinguishing the fifth program state P5 and the sixth program state P6 from each other. A seventh read voltage VR7 may be a voltage for distinguishing the sixth program state P6 and the seventh program state P7 from each other.

Referring to a table of the TLC, a first logical page bit 1st Page, a second logical page bit 2nd Page, and a third logical page bit 3rd Page according to a cell state are illustrated. The first logical page bit 1st Page, the second logical page bit 2nd Page, and the third logical page bit 3rd Page may be a Least Significant Bit (LSB), a Center Significant Bit (CSB), and a Most Significant Bit (MSB), respectively.

A read voltage applying operation may be performed for each logical page bit in a read operation of a memory block including the above-described TLCs. For example, a first read voltage applying operation of applying the fourth read voltage VR4 may be performed to read the third logical page bit 3rd Page. A second read voltage applying operation of applying the first read voltage VR1, the third read voltage VR3, and the sixth read voltage VR6 may be performed to read the second logical page bit 2nd Page. In addition, a third read voltage applying operation of applying the second read voltage VR2 and the fifth read voltage VR5 may be performed to read the first logical page bit 1st Page.

The first read voltage applying operation, the second read voltage applying operation, and the third read voltage applying operation may be sequentially performed.

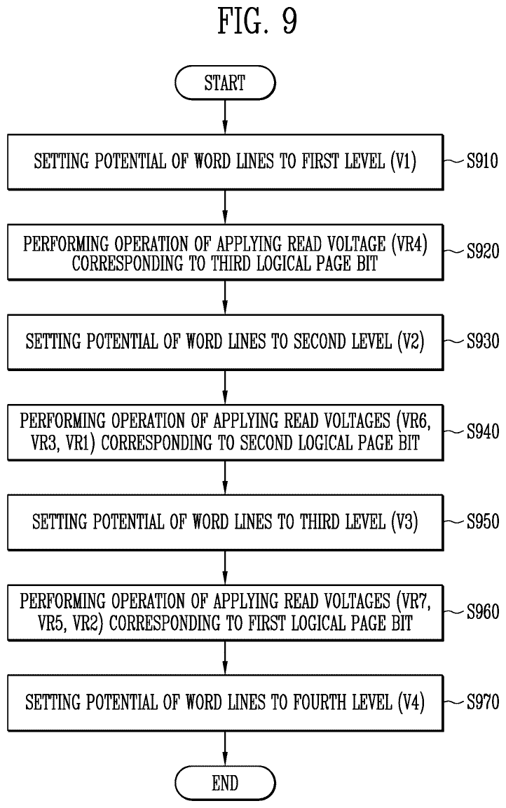

FIG. 9 is a diagram illustrating a read operation of the memory device in accordance with an embodiment of the present disclosure.

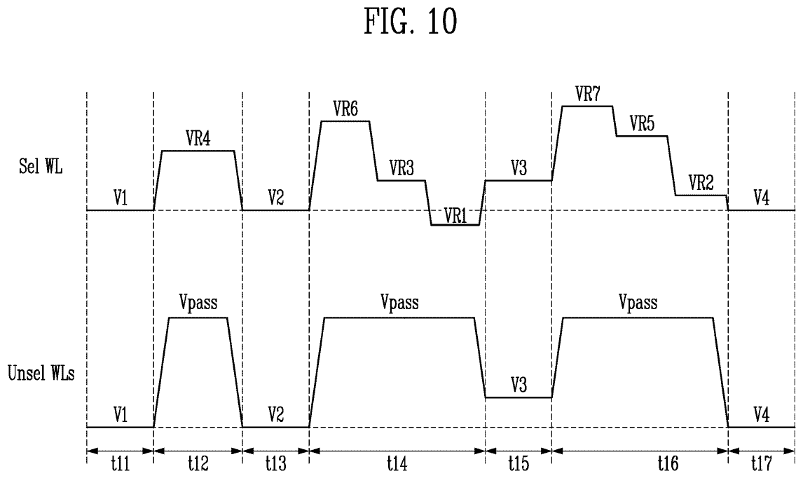

FIG. 10 is a diagram illustrating voltages applied to word lines in the read operation of the memory device in accordance with an embodiment of the present disclosure.

A read operation of the memory device in accordance with an embodiment of the present disclosure will be described as follows with reference to FIGS. 2 to 4 and 8 to 10.

In an embodiment of the present disclosure, a read operation on one selected word line of a selected memory block (e.g., MB1) including TLCs will be described as an example.

In step S910, the word line voltage setting component 310 of the control logic 300 sets, as a potential of a first voltage V1, a potential of a selected word line Sel WL and unselected word lines Unsel WLs of a selected memory block MB1. The first voltage V1 may be 0V or a positive voltage higher than 0V.

The voltage generating circuit 210 generates the first voltage V1 under the control of the word line voltage setting component 310, and the row decoder 220 applies the first voltage V1 to the selected word line Sel WL and the unselected word lines Unsel WL of the selected memory block MB1, thereby performing a word line setting operation. That is, in a duration of time t11, the first voltage V1 is applied to the selected word line Sel WL and the unselected word lines Unsel WL.

In step S920, the control logic 300 controls the peripheral circuit 200 to perform a first read voltage applying operation for reading a third logical page bit 3rd Page among a plurality of logical page bits stored in memory cells connected to the selected word line Sel WL.

The first read voltage applying operation may be an operation of applying, to the selected word line Sel WL, a fourth read voltage VR4 which can sort a data value of the third logical page bit 3rd Page as 0 or 1.

For example, the voltage generating circuit 210 may generate the fourth read voltage VR4 under the control of the control logic 300. The row decoder 220 applies the fourth read voltage VR4 to the selected word line Sel WL of the selected memory block MB1 for a certain time. Also, the voltage generating circuit 210 generates a pass voltage Vpass. The row decoder 220 applies the pass voltage Vpass to the unselected word lines Unsel WLs while the fourth read voltage VR4 is applied to the selected word line Sel WL. That is, in a duration of time t12, the fourth read voltage VR4 is applied to the selected word line Sel WL, and the pass voltage Vpass is applied to the unselected word lines Unsel WLs.

After that, the page buffer group 230 senses a voltage or current of the bit lines BL1 to BLm, thereby storing the data value of the third logical page bit 3rd Page of the memory cells connected to the selected word line Sel WL.

In step S930, the word line voltage setting component 310 of the control logic 300 sets, as a potential of a second voltage V2, the potential of the selected word line Sel WL and the unselected word lines Unsel WLs of a selected memory block MB1. The second voltage V2 may have the same potential as the first voltage V1. For example, the second voltage V2 may be 0V or a positive voltage higher than 0V.

The voltage generating circuit 210 generates the second voltage V2 under the control of the word line voltage setting component 310, and the row decoder 220 applies the second voltage V2 to the selected word line Sel WL and the unselected word lines Unsel WLs of a selected memory block MB1, thereby performing a word line setting operation. That is, in a duration of time t13, the second voltage V2 is applied to the selected word line Sel WL and the unselected word lines Unsel WLs.

In an embodiment, when the potential of the selected word line Sel WL is higher than the potential of the second voltage V2, the row decoder 220 may discharge the potential of the selected word line Sel WL and the unselected word lines Unsel WLs to a level of the second voltage V2 without the voltage generation operation of the voltage generating circuit 210.

In step S940, the control logic 300 controls the peripheral circuit 200 to perform a second read voltage applying operation for reading a second logical page bit 2nd Page among the plurality of logical page bits stored in the memory cells connected to the selected word line Sel WL.

The second read voltage applying operation may be an operation of applying, to the selected word line Sel WL, a first read voltage VR1, a third read voltage VR3, and a sixth read voltage VR6, which can sort a data value of the second logical page bit 2nd Page as 0 or 1. In the second read voltage applying operation, the sixth read voltage VR6, the third read voltage VR3, and the first read voltage VR1 may be sequentially applied to the selected word line Sel WL in an order a potential level is high among the first read voltage VR1, the third read voltage VR3, and the sixth read voltage VR6.

For example, the voltage generating circuit 210 may sequentially generate the sixth read voltage VR6, the third read voltage VR3, and the first read voltage VR1 under the control of the control logic 300. The row decoder 220 applies the sixth read voltage VR6 to the selected word line Sel WL of the selected memory block MB1 for a certain time, and then applies the third read voltage VR3 to the selected word line Sel WL of the selected memory block MB1 for a certain time. After that, the row decoder 220 applies the first read voltage VR1 to the selected word line Sel WL of the selected memory block MB1 for a certain time.

Also, the voltage generating circuit 210 generates the pass voltage Vpass. The row decoder 220 applies the pass voltage Vpass to the unselected word lines Unsel WLs while the sixth read voltage VR6, the third read voltage VR3, and the first read voltage VR1 are applied to the selected word line Sel WL. That is, in a duration of time t14, the sixth read voltage VR6, the third read voltage VR3, and the first read voltage VR1 are sequentially applied to the selected word line Sel WL, and the pass voltage Vpass is applied to the unselected word lines Unsel WLs.

After that, the page buffer group 230 senses a voltage or current of the bit lines BL1 to BLm, thereby storing the data value of the second logical page bit 2nd Page of the memory cells connected to the selected word line Sel WL.

In step S950, the word line voltage setting component 310 of the control logic 300 sets, a potential of a third voltage V3, the potential of the selected word line Sel WL and the unselected word lines Unsel WLs of the selected memory block MB1. The third voltage V3 may have a potential higher than the potential of each of the first voltage V1 and the second voltage V2. For example, the third voltage V3 may be a positive voltage higher than 0V. In an embodiment, the word line voltage setting component 310 may set the potential of the word lines to a positive voltage level higher than 0V just before a read voltage apply operation using a seventh read voltage VR7 corresponding to a seventh program state P7 as a relatively high threshold voltage distribution among a plurality of program states P1 to P7. That is, the control logic 300 may control the peripheral circuit 200 to adjust the potential of the word lines to a positive voltage level higher than 0V just before the seventh read voltage VR7 having the highest potential level among a plurality of read voltages VR1 to VR7 respectively corresponding to the plurality of program states P1 to P7 is applied to the selected word line Sel WL.

The voltage generating circuit 210 generates the third voltage V3 under the control of the word line voltage setting component 310, and the row decoder 220 applies the third voltage V3 to the selected word line Sel WL and the unselected word lines Unsel WLs of the selected memory block MB1, thereby performing a word line setting operation. That is, in a duration of time t15, the third voltage V3 is applied to the selected word line Sel WL and the unselected word lines Unsel WLs.

In an embodiment, when the potential of the selected word line Sel WL is higher than the potential of the third voltage V3, the row decoder 220 may discharge the potential of the selected word line Sel WL and the unselected word lines Unsel WLs to a level of the third voltage V3 without the voltage generation operation of the voltage generating circuit 210.

In step S960, the control logic 300 controls the peripheral circuit 200 to perform a third read voltage applying operation for reading a first logical page bit 1st Page among the plurality of logical page bits stored in the memory cells connected to the selected word line Sel WL.

The third read voltage applying operation may be an operation of applying, to the selected word line Sel WL, a second read voltage VR2, a fifth read voltage VR5, and the seventh read voltage VR7, which can sort a data value of the first logical page bit 1st Page as 0 or 1. In the third read voltage applying operation, the seventh read voltage VR7 having a high potential level among the second read voltage VR2, the fifth read voltage VR5, and the seventh read voltage VR7 may be first applied to the selected word line Sel WL, and then the fifth read voltage VR5 may be applied to the selected word line Sel WL. The fifth read voltage VR5 may be applied to the selected word line Sel WL, and then the second read voltage VR2 may be applied to the selected word line Sel WL.

For example, the voltage generating circuit 210 may sequentially generate the seventh read voltage VR7, the fifth read voltage VR5, and the second read voltage VR2 under the control of the control logic 300. The row decoder 220 applies the seventh read voltage VR7 to the selected word line Sel WL of the selected memory block MB1 for a certain time, and then applies the fifth read voltage VR5 to the selected word line Sel WL of the selected memory block MB1 for a certain time. After that, the row decoder 220 applies the second read voltage VR2 to the selected word line Sel WL of the selected memory block MB1 for a certain time.

Also, the voltage generating circuit 210 generates the pass voltage Vpass. The row decoder 220 applies the pass voltage Vpass to the unselected word lines Unsel WLs while the seventh read voltage VR7, the fifth read voltage VR5, and the second read voltage VR2 are applied to the selected word line Sel WL. That is, in a duration of time t16, the seventh read voltage VR7, the fifth read voltage VR5, and the second read voltage VR2 are sequentially applied to the selected word line Sel WL, and the pass voltage Vpass is applied to the unselected word lines Unsel WLs.

After that, the page buffer group 230 senses a voltage or current of the bit lines BL1 to BLm, thereby storing the data value of the first logical page bit 1st Page of the memory cells connected to the selected word line Sel WL.

The voltage generating circuit 210 increases the potential of the word lines, which is controlled to a positive voltage level in the duration of time t15, to a level of the seventh read voltage VR7 in the duration of time t16. In an embodiment of an operation of increasing the potential of the word lines from a level of the third voltage V3 having a positive potential to the level of the seventh read voltage VR7, an operation time is decreased and power consumption of the voltage generating circuit 210 is also decreased, as compared with an operation of increasing the potential of the word lines from 0V to the level of the seventh read voltage VR7. In step S970, the word line voltage setting component 310 of the control logic 300 sets, a potential of a fourth voltage V4, the potential of the selected word line Sel WL and the unselected word lines Unsel WLs of the selected memory block MB1. The fourth voltage V4 may have the same potential as the first voltage V1 and the second voltage V2. For example, the fourth voltage V4 may be 0V or a positive voltage higher than 0V.

The row decoder 220 may discharge the potential of the selected word line Sel WL and the unselected word lines Unsel WLs to a level of the fourth voltage V4, thereby performing a word line setting operation.

In the above-described embodiments of the present disclosure, it has been described that the potential of the word lines is set to a positive voltage level just before the seventh read voltage having a relatively highest potential among the plurality of read voltages is applied to the selected word line Sel WL. In an embodiment, the potential of the word lines may be set to a positive voltage level just before at least one read voltage having a relatively high potential among the plurality of read voltages is applied to the selected word line Sel WL. For example, the potential of the word lines may be set to the third voltage V3 just before the third read voltage applying operation using the seventh read voltage VR7, and the potential of the word lines may be set to a level which is the third voltage V3 or is lower than the third voltage V3 and higher than the first voltage V1 just before the second read voltage applying operation using the sixth read voltage VR6.

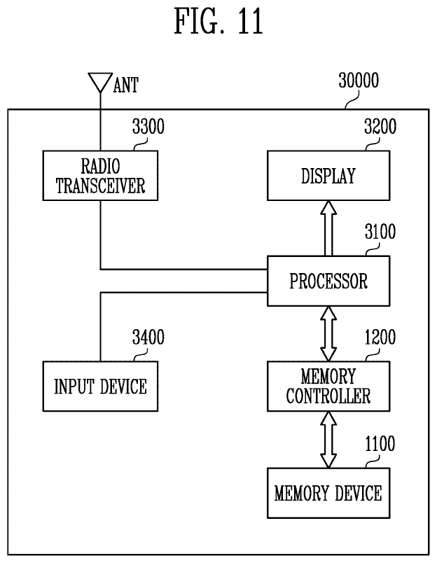

FIG. 11 is a diagram illustrating an embodiment of the memory system.

Referring to FIG. 11, the memory system 30000 may be implemented as a cellular phone, a smart phone, a tablet PC, a personal digital assistant (PDA), or a wireless communication device. The memory system 30000 may include a memory device 1100 and a memory controller 1200 capable of controlling an operation of the memory device 1100. The memory controller 1200 may control a data access operation of the memory device 1100, e.g., a program operation, an erase operation, a read operation, or the like under the control of a processor 3100.

Data programmed in the memory device 1100 may be output through a display 3200 under the control of the memory controller 1200.

A radio transceiver 3300 may transmit/receive radio signals through an antenna ANT. For example, the radio transceiver 3300 may change a radio signal received through the antenna ANT into a signal that can be processed by the processor 3100. Therefore, the processor 3100 may process a signal output from the radio transceiver 3300 and transmit the processed signal to the memory controller 1200 or the display 3200. The memory controller 1200 may transmit the signal processed by the processor 3100 to the memory device 1100. Also, the radio transceiver 3300 may change a signal output from the processor 3100 into a radio signal, and output the changed radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the memory controller 1200, data output from the radio transceiver 3300, or data output from the input device 3400 can be output through the display 3200.

In some embodiments, the memory controller 1200 capable of controlling an operation of the memory device 1100 may be implemented as a part of the processor 3100, or be implemented as a chip separate from the processor 3100. In addition, the memory controller 1200 may be implemented as an example of the memory controller 1200 shown in FIG. 1, and the memory device 1100 may be implemented as an example of the memory device 1100 shown in FIG. 2.

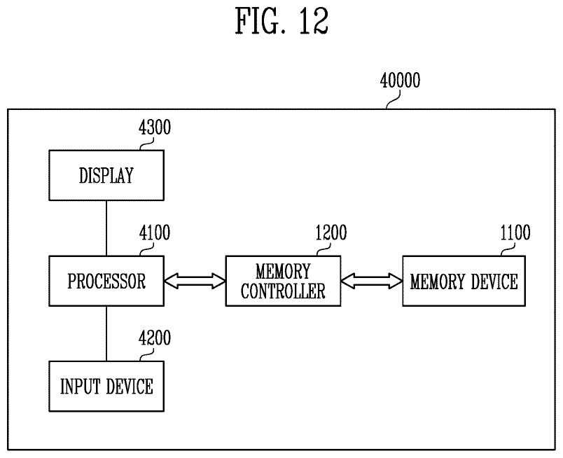

FIG. 12 is a diagram illustrating an embodiment of the memory system.

Referring to FIG. 12, the memory system 40000 may be implemented as a personal computer (PC), a tablet PC, a net-book, an e-reader, a personal digital assistant (PDA), a portable multi-media player (PMP), an MP3 player, or an MP4 player.

The memory system 40000 may include a memory device 1100 and a memory controller 1200 capable of controlling a data processing operation of the memory device 1100.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the memory controller 1200. In some embodiments, the memory controller 1200 capable of controlling an operation of the memory device 1100 may be implemented as a part of the processor 4100, or be implemented as a chip separate from the processor 4100. In addition, the memory controller 1200 may be implemented as an example of the memory controller 1200 shown in FIG. 1, and the memory device 1100 may be implemented as an example of the memory device 1100 shown in FIG. 2.

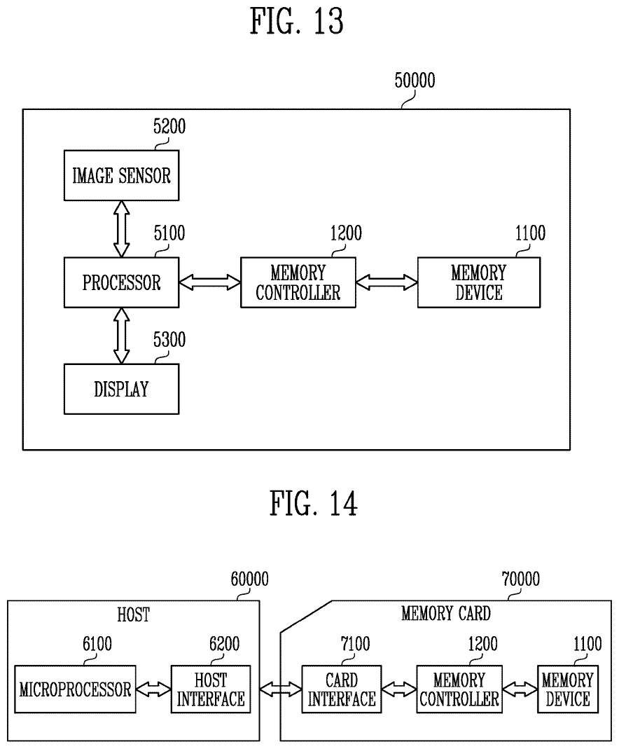

FIG. 13 is a diagram illustrating an embodiment of the memory system.

Referring to FIG. 13, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a memory controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the memory controller 1200. Under the control of the processor 5100, the converted digital signals may be output through a display 5300, or be stored in the memory device 1100 through the memory controller 1200. In addition, data stored in the memory device 1100 may be output through the display 5300 under the control of the processor 5100 or the memory controller 1200.

In some embodiments, the memory controller 1200 capable of controlling an operation of the memory device 1100 may be implemented as a part of the processor 5100, or be implemented as a chip separate from the processor 5100. In addition, the memory controller 1200 may be implemented as an example of the memory controller 1200 shown in FIG. 1, and the memory device 1100 may be implemented as an example of the memory device 1100 shown in FIG. 2.

FIG. 14 is a diagram illustrating an embodiment of the memory system.

Referring to FIG. 14, the memory system 70000 may be implemented as a memory card or a smart card. The memory system 70000 may include a memory device 1100, a memory controller 1200, and a card interface 7100.

The memory controller 1200 may control data exchange between the memory device 1100 and the card interface 7100. In some embodiments, the card interface 7100 may be a secure digital (SD) card interface or a multi-media card (MMC) interface, but the present disclosure is not limited thereto. In addition, the memory controller 1200 may be implemented as an example of the memory controller 1200 shown in FIG. 1, and the memory device 1100 may be implemented as an example of the memory device 1100 shown in FIG. 2.

The card interface 7100 may interface data exchange between a host 60000 and the memory controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is connected to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the memory controller 1200 under the control of a microprocessor 6100.

In accordance with an embodiment of the present disclosure, a potential of word lines is set to a positive voltage level before a read voltage corresponding to a relatively high program state is applied in a read operation, thereby shortening a rising time of a read voltage. Accordingly, the speed of the read operation can be increased, and power consumption can be reduced.

While the present disclosure has been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a memory block including a plurality of memory cells;
a peripheral circuit configured to perform a plurality of read voltage applying operations and a plurality of word line setting operations on the memory block; and
control logic configured to control the peripheral circuit to perform a plurality of word line setting operations to set a plurality of word line potentials of word lines included in the memory block, wherein at least one word line setting operation among the plurality of word line setting operations is used to set a word line potential higher than a word line potential set by the other word line setting operations.

2. The memory device of claim 1, wherein the plurality of memory cells are capable of being in an erase state and a plurality of program states, and the peripheral circuit applies, to a selected word line among the word lines, at least one read voltage among a plurality of read voltages for distinguishing the erase state and the plurality of program states in each of the plurality of read voltage applying operations.

3. The memory device of claim 2, wherein the peripheral circuit:
performs any one of the plurality of word line setting operations between the plurality of read voltage applying operations; and
performs the at least one word line setting operation just before a specific read voltage applying operation using at least one highest read voltage among the plurality of read voltage applying operations is performed.

4. The memory device of claim 2, wherein each of the plurality of read voltage applying operations corresponds to a least significant bit, a center significant bit, and a most significant bit of the memory cells.

5. The memory device of claim 1, wherein the peripheral circuit controls the word lines to have a first voltage level in the at least one word line setting operation, and controls the word lines to have a second voltage level in the other word line setting operations, and
wherein the first voltage level is a positive voltage level higher than zero volts.

6. The memory device of claim 5, wherein the peripheral circuit controls the word lines to have the second voltage level before a first read voltage applying operation among the plurality of read voltage applying operations is performed.

7. The memory device of claim 5, wherein the peripheral circuit controls the word lines to have the second voltage level after a last read voltage applying operation among the plurality of read voltage applying operations is performed.

8. The memory device of claim 1, wherein the control logic includes a word line voltage setting component, and
wherein the word line voltage setting component is configured to set a word line potential in each of the plurality of word line setting operations.

9. A memory device comprising:
a memory block including a plurality of memory cells;
a peripheral circuit configured to alternately perform a plurality of read voltage applying operations and a plurality of word line setting operations on the memory block; and
control logic configured to set a first specific word line setting operation among the plurality of word line setting operations, which is performed just before a first specific read voltage applying operation using a highest read voltage among the plurality of read voltage applying operations, to a word line potential higher than a word line potential of the other word line setting operations, and control the peripheral circuit such that word lines of the memory block have the set word line potential.

10. The memory device of claim 9, wherein the control logic sets a second specific word line setting operation among the plurality of word line setting operations, which is performed just before a second specific read voltage applying operation using a second highest read voltage among the plurality of read voltage applying operations, to a word line potential which is lower than the word line potential of the first specific word line setting operation and is higher than a word line potential of the other word line setting operations except the first specific word line setting operation and the second specific word line setting operation.

11. The memory device of claim 10, wherein the peripheral circuit controls the word lines to have a first voltage level in the first specific word line setting operation, and controls the word lines to have a second voltage level in the other word line setting operations except the first specific word line setting operation and the second specific word line setting operation, and
wherein the first voltage level is a positive voltage level higher than zero volts.

12. The memory device of claim 11, wherein the peripheral circuit controls the word lines to have a third voltage level in the second specific word line setting operation, and
wherein the third voltage level is a positive voltage level higher than zero volts.

13. The memory device of claim 11, wherein the peripheral circuit controls the word lines to have the second voltage level before a first read voltage applying operation among the plurality of read voltage applying operations is performed.

14. The memory device of claim 11, wherein the peripheral circuit controls the word lines to have the second voltage level after a last read voltage applying operation among the plurality of read voltage applying operations is performed.

15. A method of operating a memory device, the method comprising:
performing a first word line setting operation of controlling a plurality of word lines of a memory block to have a first voltage level;
performing a first read voltage applying operation on a selected word line;
performing a second word line setting operation of controlling the selected word line to have a second voltage level after the first read voltage applying operation is performed;
performing a second read voltage applying operation on the selected word line;
performing a third word line setting operation of controlling the selected word line to have a third voltage level after the second read voltage applying operation is performed; and
performing a third read voltage applying operation on the selected word line,
wherein the third voltage level of the third word line setting operation performed just before the third read voltage applying operation using a highest read voltage among the first read voltage applying operation, the second read voltage applying operation, and the third read voltage applying operation is performed is higher than each of the first voltage level and the second voltage level.

16. The method of claim 15, wherein the third voltage level is higher than zero volts.

17. The method of claim 15, wherein the second voltage level of the second word line setting operation performed just before the second read voltage applying operation using a second highest read voltage among the first read voltage applying operation, the second read voltage applying operation, and the third read voltage applying operation is performed is higher than the first voltage level and is lower than the third voltage level.

18. The method of claim 17, wherein the second voltage level is higher than zero volts.

19. The method of claim 15, wherein the first read voltage applying operation is an operation for reading a least significant bit of memory cells connected to the selected word line,
wherein the second read voltage applying operation is an operation for reading a center significant bit of the memory cells, and
wherein the third read voltage applying operation is an operation for reading a most significant bit of the memory cells.

20. The method of claim 15, wherein the first read voltage applying operation is an operation for reading a most significant bit of memory cells connected to the selected word line,
wherein the second read voltage applying operation is an operation for reading a center significant bit of the memory cells, and
wherein the third read voltage applying operation is an operation for reading a least significant bit of the memory cells.

21. The method of claim 15, further comprising performing a fourth word line setting operation of controlling the selected word line to have a fourth voltage level after the performing of the third read voltage applying operation on the selected word line,
wherein the fourth voltage level is lower than the third voltage level.
